(19) United States
(12) Patent Application Publication
(10) Pub. No.: US 2008/0253092 A1
(43) Pub. Date: Oct. 16, 2008

(54) Heat Dissipation System for Photovoltaic Interconnection System

(75) Inventors: Scott Stephen Duesterhoeft, Etters, PA (US); Christopher George Daily, Harrisburg, PA (US)

Correspondence Address: TYCO TECHNOLOGY RESOURCES, 4550 NEW LINDEN HILL ROAD, SUITE 140, WILMINGTON, DE, 19808-2952, US

(73) Assignee: TYCO ELECTRONICS CORPORATION, Middletown, PA (US)

(21) Appl. No.: 11/735,065

(22) Filed: Apr. 13, 2007

(51) Int. Cl. H05K 7/20

(52) U.S. Cl. 361/710

(57) ABSTRACT

A heat dissipation system for a photovoltaic array interconnection system includes an enclosure and a heat dissipating assembly. The heat dissipating assembly includes a heat dissipating portion and at least one heat emitting electrical component. Each heat emitting electrical component has a heat sink element attached thereto for dissipating heat generated by the heat emitting electrical component. The heat dissipating portion is sufficiently proximate to at least an additional portion of the at least one heat emitting electrical component to further dissipate heat generated by the at least one heat emitting electrical component. The heat dissipating portion includes at least one electrical contact electrically connected to the at least one heat emitting electrical component. The enclosure is configured for receiving at least a portion of the heat dissipating portion and for receiving external power input wiring by electrical contact with the at least one electrical contact.

### FIELD OF THE INVENTION

The present invention is directed to a heat dissipation system for a photovoltaic array interconnection system, and more particularly to a heat dissipation portion permitting higher current carrying capacity.

### BACKGROUND OF THE INVENTION

Photovoltaic (PV) modules or arrays produce electricity from solar energy. Electrical power produced by PV modules reduces the amount of energy required from non-renewable resources such as fossil fuels and nuclear energy. Significant environmental benefits are also realized from solar energy production, for example, reduction in air pollution from burning fossil fuels, reduction in water and land use from power generation plants, and reduction in the storage of waste byproducts. Solar energy produces no noise, and has few moving components. Because of their reliability, PV modules also reduce the cost of residential and commercial power to consumers.

PV cells are essentially large-area semiconductor diodes. Due to the photovoltaic effect, the energy of photons is converted into electrical power within a PV cell when the PV cell is irradiated by a light source, such as sunlight. PV cells are typically interconnected into solar modules that have power ranges of up to 100 watts (W) or greater. For large PV systems, special PV modules are produced with a typical power range of up to several 100 W. A photovoltaic module is the basic element of a photovoltaic power generation system. A PV module has many solar cells interconnected in series or parallel, according to the desired voltage and current parameters. PV cells may be connected and placed between a polyvinyl plate on the bottom and a tempered glass on the top. PV cells are typically interconnected with thin contacts on the upper side of the semiconductor material. The amount of power generated by typical crystalline modules ranges from several W to up to 150 W/module.

In the case of facade or roof systems, the photovoltaic system may be installed during construction, or added to the building after the building has been constructed. Roof systems are generally lower powered systems, e.g., 10 kW, to meet typical residential loads. Roof integrated photovoltaic systems may consist of different module types, such as crystalline and micro-perforated amorphous modules. Roof-integrated photovoltaic systems may be integrated into the roof in the form of roof tiles such that the entire roof or a portion thereof is covered with photovoltaic modules, or the systems are added to the roof after roof construction has been completed.

PV modules/arrays require specially designed devices adapted for interconnecting the various PV modules/arrays with each other, and with electrical power distribution systems. PV connection systems are used to accommodate serial and parallel connection of PV arrays. In addition to connection or junction boxes or enclosures, a PV connection system includes connectors that allow for speedy field installation or high-speed manufacture of made-to-length cable assemblies. Connections, connection enclosures or junction boxes may be required to receive specialized cable terminations from PV modules/arrays, with internally mounted power diodes for controlling current flow to the load. Thus, certain connection enclosure configurations may generate internal heat, which must be dissipated in order to protect the internal components and external structures adjacent to the connection enclosure. In many cases, governmental regulations and industry standards establish a maximum permissible temperature that can be attained.

Therefore, there is a need for an improved system for dissipating heat generated by electrical/electronic components disposed inside of the enclosure.

### SUMMARY OF THE INVENTION

A first aspect of the present invention includes a heat dissipation system for a photovoltaic array interconnection system. The system includes an enclosure and a heat dissipating system. The heat dissipating system includes a heat dissipating portion and at least one heat emitting electrical component. Each heat emitting electrical component has a heat sink element attached thereto for dissipating heat generated by the heat emitting electrical component. The heat dissipating portion is sufficiently proximate to at least an additional portion of the at least one heat emitting electrical component to further dissipate heat generated by the at least one heat emitting electrical component. The heat dissipating portion includes at least one electrical contact electrically connected to the at least one heat emitting electrical component. The enclosure is configured for receiving at least a portion of the heat dissipating portion and for receiving external power input wiring by electrical contact with the at least one electrical contact.

Another aspect of the present invention includes an interconnection system for solar cell arrays in a power distribution system. The system includes at least one electrical current producing device and a junction box connecting a plurality of the current producing devices. The junction box includes an enclosure and a heat dissipating system. The heat dissipating system includes a heat dissipating portion and at least one heat emitting electrical component. Each heat emitting electrical component has a heat sink element attached thereto for dissipating heat generated by the heat emitting electrical component. The heat dissipating portion is sufficiently proximate to at least an additional portion of the at least one heat emitting electrical component to further dissipate heat generated by the at least one heat emitting electrical component. The heat dissipating portion includes at least one electrical contact electrically connected to the at least one heat emitting electrical component. The enclosure is configured for receiving at least a portion of the heat dissipating portion and for receiving external power input wiring by electrical contact with the at least one electrical contact.

Yet another aspect of the present invention includes an interconnection system for solar cell arrays in a power distribution system. The system includes at least one electrical current producing device and a junction box connecting a plurality of the current producing devices. The junction box includes an enclosure and a heat dissipating assembly. The heat dissipating assembly includes a heat dissipating portion and at least one diode, each diode having a heat sink element attached thereto for dissipating heat generated by the diode. The heat dissipating portion is sufficiently proximate to at least an additional portion of the at least one diode to further dissipate heat generated by the at least one diode. The heat dissipating portion includes at least one electrical contact electrically connected to the at least one diode. The enclosure is configured for receiving at least a portion of the heat dissipating portion and for receiving external power input wiring by electrical contact with the at least one electrical contact.

An advantage of an embodiment of the present invention is improved heat dissipation from the components within the junction box.

Another advantage of an embodiment of the present invention is that a plurality of PV components may be connected to a single junction box.

Still another advantage of an embodiment of the present invention is that additional components, components having increased heat emission and/or PV components having increased current capacity may be utilized within the junction box.

Still another advantage of an embodiment of the present invention is that the system is easily fabricated and allows additional environmental protection for the electrical components present in the junction box.

Other features and advantages of the present invention will be apparent from the following more detailed description of the preferred embodiment, taken in conjunction with the accompanying drawings which illustrate, by way of example, the principles of the invention.

### BRIEF DESCRIPTION OF THE DRAWINGS

FIG. 1 shows a top perspective view of an interconnection system for solar cell arrays in a power distribution system according to an embodiment of the present invention.

FIG. 2 shows an exploded perspective top view of an interconnection system for solar cell arrays in a power distribution system according to an embodiment of the present invention.

FIG. 3 shows an exploded perspective side view of a heat dissipating assembly according to an embodiment of the present invention.

FIGS. 4-6 show reverse top perspective views and a side perspective view, respectively, of an embodiment of an assembled heat dissipating assembly according to the present invention.

Wherever possible, the same reference numbers are used throughout the drawings to refer to the same or like parts.

### DETAILED DESCRIPTION OF THE INVENTION

The present invention is directed to a heat dissipation system for a photovoltaic array interconnection system for interconnection of solar cell arrays for dissipating heat emitted from electrical components. The heat dissipation system conducts the heat from a diode and emits the heat inside a sealed junction box, then to the surrounding environment.

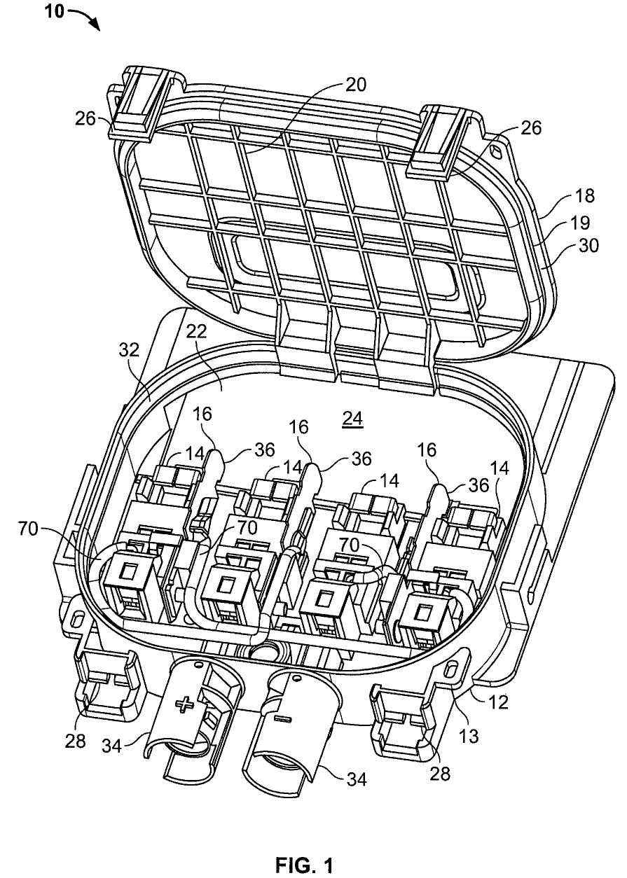

FIG. 1 includes an interconnection system 10 according to an embodiment of the present invention. Interconnection system 10 includes an enclosure or junction box 12. In one embodiment, junction box 12 includes a base 13 having an opening 22 for hingedly receiving a cover 18. As further shown, opening 22 includes an inner periphery 32 that receives an outer periphery 30 of cover 18 containing a gasket 19, providing a fluid tight seal when cover 18 is secured to base 13. Latch portions 26 extending from cover 18 and corresponding latch portions 28 formed in base 13 provide a locking engagement therebetween, retaining cover 18 and base 13 in an installed position. Junction box 12 can be constructed of a substantially rigid, electrically insulating material, such as an ABS plastic or other suitable material. In one embodiment, junction box 12 has enhanced thermal conductivity.

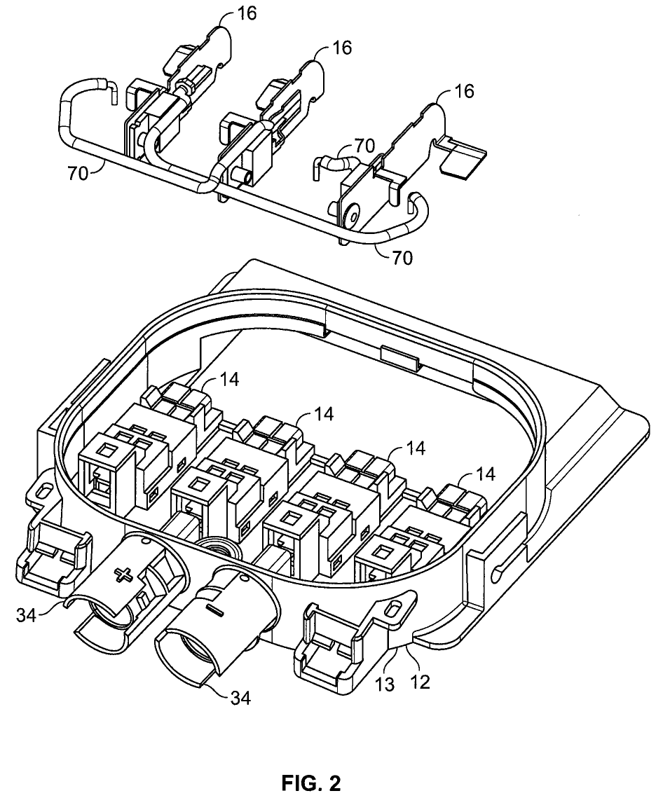

As shown in FIGS. 1-2, rail assemblies 14 mounted within junction box 12 connect conductors of the PV array (not shown). In one construction, four rail assemblies 14 are arranged in junction box 12, although other numbers of rail assemblies 14 can be used. Heat dissipating assemblies 16 are disposed adjacent to the rail assemblies 14 to combine the electrical current flowing through rail assemblies 14 to a pair of sockets 34 for receiving external power connectors associated with the PV array. In one embodiment, the sockets 34 are hollow cylindrical conduits that encompass mating posts (not shown) that extend from exterior of the junction box 12 to a position inside junction box 12, in electrical communication with corresponding rail assemblies 14. The sockets 34 may be configured for bayonet-type locking engagement, threaded engagement, or any other connections known in the art. Polarization features (not shown) may be incorporated into the sockets 34 to ensure proper polarity of the external connections with the junction box 12. The mating posts are preferably provided in pairs for each junction box 12, although boxes may be configured with a singular mating post, three posts, or other arrangements, as required by the interconnection of heat dissipating assemblies 16. The mating posts are electrical conductors for connecting the external power distribution (not shown) to the rail assemblies 14. The mating posts are insert molded or otherwise formed or pressed within junction box 12, thereby maintaining a fluid tight seal with the junction box 12.

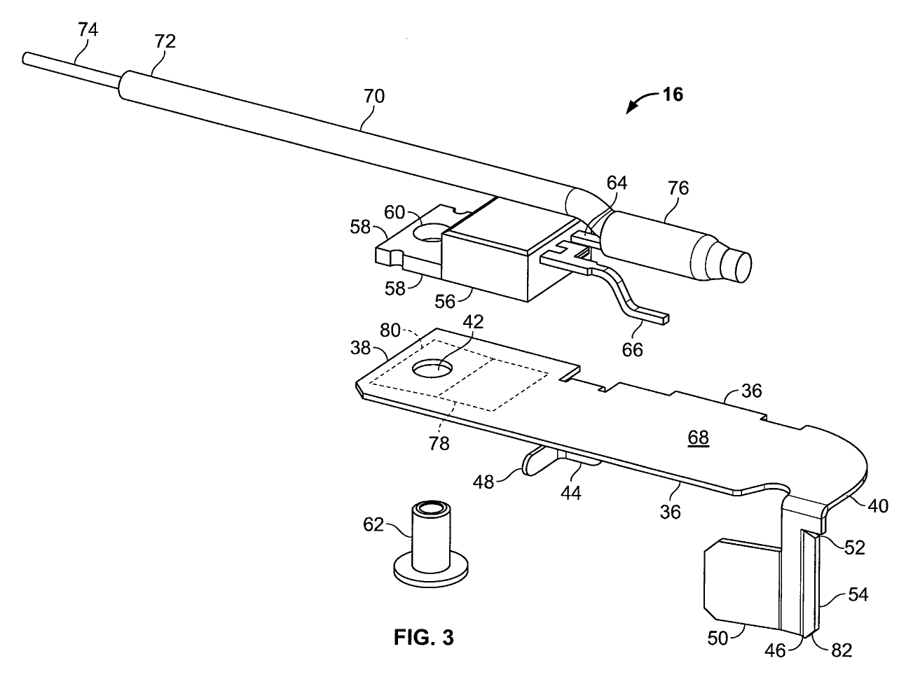

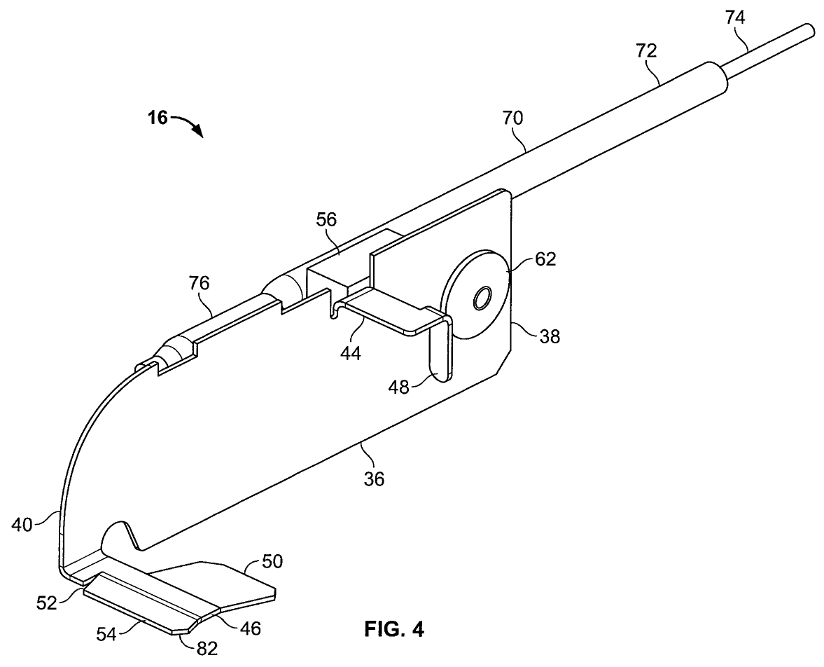

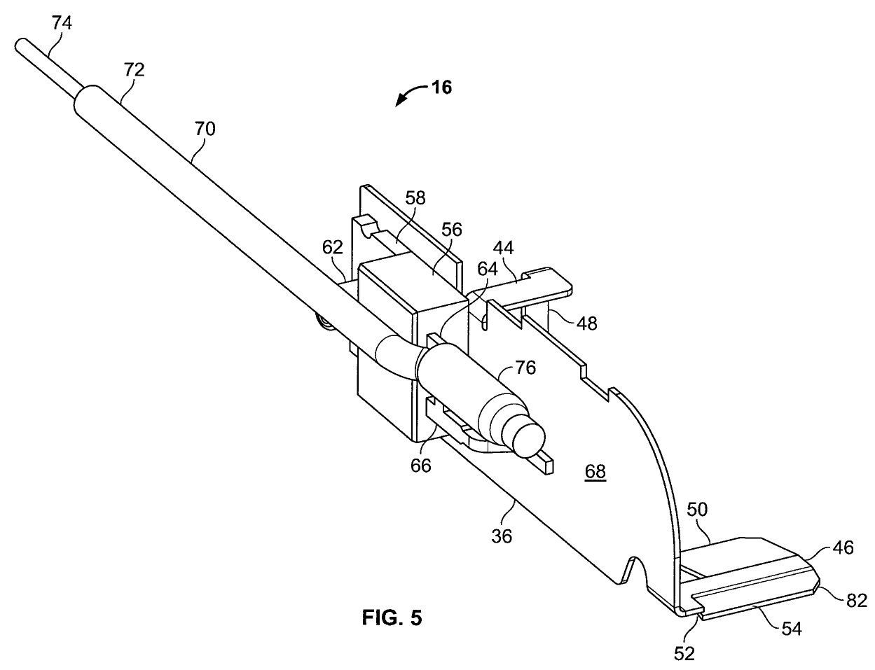

As shown in FIGS. 3-6, heat dissipating assembly 16 includes a heat dissipating portion 36 having opposed ends 38, 40. Heat dissipating portion 36 includes a leg 46 extending substantially transversely outward from heat dissipating portion 36 adjacent to end 40, with leg 46 further extending to a tab 50 extending at an angle from leg 46 to engage rail assembly 14 (FIG. 2). In one embodiment, leg 46 includes a slit 52, defining a stiffening portion 54 formed substantially parallel to the length of leg 46. Stiffening portion 54 provides enhanced structural stiffness and strength to secure heat dissipating portion 36 in position when engaged with rail assembly 14. In one embodiment, a chamfer 82 is formed at an end of stiffening portion 54 opposite slit 52 to more easily engage rail assembly 14. Similarly, formed between ends 38, 40 is a leg 44 extending outwardly from heat dissipating portion 36, which leg 44 further extending to a tab 48 for structurally engaging rail assembly 14. In one embodiment, heat dissipating portions 36 can be used as modules, i.e., virtually identical in construction, or alternately, with some elements of heat dissipating portions 36 constructed in mirror image with each other, as shown in FIG. 2. Such modular construction provides multiple advantages, including reduced costs associated with manufacturing, placement and replacement of heat dissipating assemblies 16.

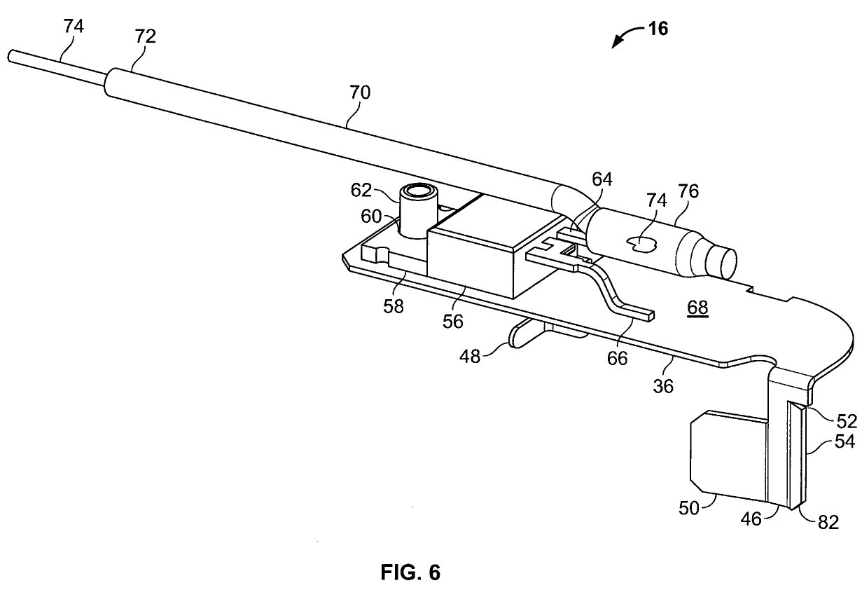

Additionally, in one embodiment, heat dissipating portion 36 is constructed of an electrically conductive material, such as a copper and/or an aluminum alloy. An advantage of using an electrically conductive heat dissipating portion 36 permits a direct electrical connection between heat dissipating portion 36 and a heat emitting electrical component or diode 56. Use of diode 56 provides a controlled, one-way flow of electrical current between jumpered heat dissipating assemblies 16. As shown in FIG. 6, diode 56 includes a heat sink element 58 having an opening 60. A fastener 62, such as a rivet, can be directed through opening 60 and an aligned opening 42 formed in heat dissipating portion 36 to secure diode 56 to a surface 68 of heat dissipating portion 36.

The heat emitting electrical device or diode 56 for use with the present invention may include TO-220 packaged diodes. The TO-220 packaged diodes preferably contain heat sink elements 58, such as heat sink elements 58 fabricated from copper, that assist with dissipating heat and help to meet the temperature standard of IEC 61215 Edition 2 or other suitable industry standard or specification. The present invention may also use ITO-220AC diodes that have plastic covered heat sink elements 58 and help to dissipate any generated heat to meet the IEC 61215 Edition 2. In addition to the TO-220 diode and ITO-220AC diode, any other similar and suitable diode that can meet the IEC 61215 Edition 2 standard may be used with the present invention.

As shown in FIG. 3, which is prior to its installed or fastened position, heat sink element 58 of diode 56 is brought into physical contact and/or close proximity with an area 80 of surface 68 of heat dissipating portion 36. By virtue of this close proximity and/or contact, thermal energy generated by diode 56 that is conducted through heat sink element 58 is then conducted into heat dissipating portion 36. Similarly, the body of diode 56 is also brought into physical contact and/or close proximity with an area 78 of surface 68 of heat dissipating portion 36. By virtue of this close proximity, thermal energy generated by the body of diode 56 is then conducted into heat dissipating portion 36, permitting additional removal of thermal energy from diode 56. In one embodiment, heat dissipating portion 36 conforms to one or more of the surfaces of diode 56 and/or heat sink element 58. Additionally, at least a portion of surfaces 78, 80 can be coated with a layer of thermally conductive material to further enhance heat dissipation from the diode 56 and heat sink element 58, the geometry of heat dissipating portion 36 is not limited to the geometries shown and may include any geometry that provides a surface area capable of heat dissipation.

In one embodiment, a lead 66 extending from diode 56 is bonded to surface 68 of heat dissipating portion 36, such as by soldering or other method providing electrical communication therebetween. A lead 64 extending from diode 56 is bonded to an exposed conductor 74 of a jumper wire 70 by removing a sufficient amount of insulation 72 from each end of wire 70. Once insulation 72 is removed, one conductor 74 is brought toward lead 64, and an insulating tube 76 is installed over lead 64 and conductor 74 to establish electrical communication therebetween. In one embodiment, conductor 74 and lead 64 are bonded together, such as by soldering, in which insulating tube 76 is not required. The exposed end of conductor 74 opposite insulating tube 76 can then be used to connect to rail assemblies 14. In one embodiment, FIG. 2 shows an arrangement of wires 70 extending from corresponding heat dissipating assemblies 16, with FIG. 1 showing the wires 70. In other words, wires 70 selectively jumper electrical current flow between rail assemblies 14 to control the flow of electrical current.

It is to be understood that while diodes are disclosed, the present invention can also be used with other electrical components to dissipate thermal energy generated by those components.

An opening 24 (FIG. 1) may be provided on one side of junction box 12 to allow connections for incoming power conductors from the solar cell array (not shown). This opening 24 is typically oriented against a flat surface of a solar panel (not shown) which is sealed to the outside elements around the periphery of the junction box 12 and the opening 24 to provide environmental protection. The present invention is not limited to embodiments including openings and may include covers, hinged apertures or any other suitable structure that permits access to rail assembly 14.

While the invention has been described with reference to a preferred embodiment, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A heat dissipation system for a photovoltaic array interconnection system comprising:
an enclosure and a heat dissipating assembly;
the heat dissipating assembly includes a heat dissipating portion and at least one heat emitting electrical component, each heat emitting electrical component having a heat sink element attached to the heat dissipating portion for dissipating heat generated by the heat emitting electrical component, the heat dissipating portion being sufficiently proximate to at least an additional portion of the at least one heat emitting electrical component to further dissipate heat generated by the at least one heat emitting electrical component, the heat dissipating portion including at least one electrical contact electrically connected to the at least one heat emitting electrical component; and
the enclosure is configured for receiving at least a portion of the heat dissipating portion and for receiving external power input wiring by electrical contact with the at least one electrical contact.

2. The system of claim 1 wherein the heat dissipating portion is composed of an electrically conductive material.

3. The system of claim 1 wherein the enclosure includes a first opening for receiving a cover, and a second opening disposed opposite the first opening for receiving external power input wiring by electrical contact with the at least one electrical contact.

4. The system of claim 1 wherein the heat dissipating portion comprising a thermally conductive material covering at least a portion of the heat dissipating portion in contact with or in close proximity to the heat sink and heat emitting electrical component, the thermally conductive material further comprising a surface area that is capable of dissipating heat.

5. The system of claim 1 wherein the at least one heat emitting electrical component is a diode.

6. The system of claim 1 wherein the at least one heat emitting electrical component is a plurality of diode elements being TO-220 packaged diodes, wherein the TO-220 packaged diodes further comprising heat sink tabs for dissipating heat.

7. The system of claim 1 wherein the at least one heat emitting electrical component is a plurality of diode elements being ITO-220AC diodes, wherein the ITO-220AC diodes having plastic covered heat sinks to dissipate heat at a rate sufficient to meet the requirements of IEC 61215 Edition 2.

8. The system of claim 1 wherein the enclosure and the heat dissipating portion are both comprised of a thermally conductive material.

9. The system of claim 1 wherein the enclosure is constructed of a non-electrically conductive polymeric material.

10. The system of claim 1 wherein the enclosure is constructed of a substantially rigid, electrically insulating and thermally conductive material.

11. The system of claim 10, wherein the material is an ABS plastic.

12. The system of claim 1 wherein the electrical contacts are secured to the heat dissipating portion with a solder connection to receive the external power input wiring.

13. The system of claim 1, wherein the heat dissipating portion further comprises a secondary heat sink element formed on a surface of the thermally conductive material.

14. The system of claim 13, further comprising a fin disposed on the secondary heat sink.

15. An interconnection system for solar cell arrays in a power distribution system, the system comprising:
at least one electrical current producing device; and
a junction box connecting a plurality of the current producing devices, the junction box comprising:
an enclosure and a heat dissipating assembly;
the heat dissipating assembly includes a heat dissipating portion and at least one heat emitting electrical component, each heat emitting electrical component having a heat sink element attached thereto for dissipating heat generated by the heat emitting electrical component, the heat dissipating portion being sufficiently proximate to at least an additional portion of the at least one heat emitting electrical component to further dissipate heat generated by the at least one heat emitting electrical component, the heat dissipating portion including at least one electrical contact electrically connected to the at least one heat emitting electrical component; and
the enclosure is configured for receiving at least a portion of the heat dissipating portion and for receiving external power input wiring by electrical contact with the at least one electrical contact.

16. The system of claim 15, wherein the at least one current producing device is a photovoltaic cell.

17. The system of claim 15, wherein the at least one current producing device is a photovoltaic array.

18. The system of claim 15, wherein the heat dissipating portion is disposed in thermal communication with the enclosure.

19. An interconnection system for solar cell arrays in a power distribution system, the system comprising:
at least one electrical current producing device; and
a junction box connecting a plurality of the current producing devices, the junction box comprising:
an enclosure and a heat dissipating assembly;
the heat dissipating assembly includes a heat dissipating portion and at least one diode, each diode having a heat sink element attached thereto for dissipating heat generated by the diode, the heat dissipating portion being sufficiently proximate to at least an additional portion of the at least one diode to further dissipate heat generated by the at least one diode, the heat dissipating portion including at least one electrical contact electrically connected to the at least one diode; and
the enclosure is configured for receiving at least a portion of the heat dissipating portion and for receiving external power input wiring by electrical contact with the at least one electrical contact.

20. The system of claim 19 wherein the at least one diode is a TO-220 packaged diode further comprising heat sink tabs for dissipating heat and/or an ITO-220AC diode, wherein the ITO-220AC diodes having plastic covered heat sinks to dissipate heat at a rate sufficient to meet the requirements of IEC 61215 Edition 2.
